(19) United States
(12) Patent Application Publication
(10) Pub. No.: US 2026/0096439 A1
(43) Pub. Date: Apr. 2, 2026

(54) LAMINATE SUBSTRATE FOR A RADIOFREQUENCY DEVICE

(71) Applicant: STMicroelectronics International N.V., Geneva (CH)

(72) Inventor: Vipin VELAYUDHAN, Grenoble (FR)

(73) Assignee: STMicroelectronics International N.V., Geneva (CH)

(21) Appl. No.: 19/342,861

(22) Filed: Sep. 29, 2025

(30) Foreign Application Priority Data
Oct. 1, 2024 (FR) FR2410540

(51) Int. Cl. H01L 23/66; G01S 13/931; H01P 3/08; H01P 11/00; H01Q 1/32; H01Q 9/04

(52) U.S. Cl. CPC H10W 44/20; H01P 3/081; H01P 11/003; H01Q 1/32; H01Q 9/0414; G01S 13/931; H10W 44/216; H10W 44/248

(57) ABSTRACT

A laminate substrate for an RF application includes: a first metal layer in which is formed a first slot and a transmission line penetrating into the first slot; a second metal layer comprising a second laterally closed slot; a third metal layer comprising a third laterally closed slot; a fourth metal layer comprising a fourth slot; a dielectric layer being arranged between each metal layer; the second slot, the third slot, and the fourth slot forming a vertical RF feedthrough in the substrate; at least one of the third metal layer or the fourth metal layer having a portion protruding, respectively, into the third slot or into the fourth slot.

### PRIORITY CLAIM

This application claims the priority benefit of French Application for Patent No. FR2410540, filed on Oct. 1, 2024, the content of which is hereby incorporated by reference in its entirety to the maximum extent allowable by law.

### TECHNICAL FIELD

The present disclosure generally concerns substrates for an electronic device transmitting and/or receiving radio frequency signals. Such devices find applications, for example, in the field of automotive radars, for example in automotive advanced driver assistance systems (ADAS).

### BACKGROUND

Typically, in automotive advanced driver assistance systems (ADAS) devices, radio frequency signals (76 GHz-81 GHz) are transmitted and received by antennas. The transmission and reception delays are used to calculate the distance of the object. Then, a plurality of radars with image processing algorithms are used to identify the shape of the object. This type of system or function is called RADAR.

Devices may have a plurality of architectures. In devices having a launcher-on-package (LoP) architecture, a chip is placed on the top surface of a substrate of BGA (ball grid array) type, itself arranged on a printed circuit board (PCB) provided with through holes. An antenna guide module comprising an antenna and a waveguide is placed on the other side of the PCB.

Thus, signals can be routed from the chip to the antenna module via the PCB.

To transmit a signal from the chip to the PCB, patch antennas, in the form of metal plates, are positioned on the bottom surface of the BGA substrate, and arranged in correspondence with the through holes of the PCB. They have a specific shape and size to resonate at the desired frequency. However, the RF connection through the BGA substrate and the antenna may cause both a transmission loss and a bandwidth loss. A frequency shift and/or decrease can also be observed. A known solution to this problem is to create larger through holes in the printed circuit board, which increases the size of the final device.

There exists a need to improve signal transmission and/or to increase the bandwidth of the signal without increasing the size of the device.

There is a need to overcome all or part of the disadvantages of known devices.

### SUMMARY

An embodiment provides a laminate substrate for an RF application comprising, from a first main side to a second main side: a first metal layer and a transmission line, a first slot open on one of its sides being formed in the first metal layer, the transmission line being coplanar with the first metal layer and penetrating into the first slot; a second metal layer comprising a second laterally closed slot; a third metal layer comprising a third laterally closed slot; a fourth metal layer comprising a fourth slot; a dielectric layer being arranged between each metal layer, the second slot, the third slot, and the fourth slot forming a vertical RF feedthrough in the substrate; and at least one of the third metal layer or of the fourth metal layer having a portion protruding, respectively, into the third slot or into the fourth slot.

According to an embodiment, the third metal layer and the fourth metal layer each have a portion protruding, respectively, into the third slot and the fourth slot.

According to an embodiment, the protruding portions have different dimensions and/or are offset from one another.

According to an embodiment, the substrate thickness is in the range from 100 to 200 μm, for example in the order of 150 μm.

According to an embodiment, the protruding portion(s) are rectangular.

According to an embodiment, the second slot, the third slot, and the fourth slot have different dimensions.

According to an embodiment, the fourth slot has dimensions greater than the dimensions of the second slot.

Another embodiment provides a radio frequency device comprising: the substrate such as previously defined; a radio frequency chip mounted on the first surface of the substrate, the radio frequency chip being connected to the feed line, whereby the radio frequency chip is coupled to the vertical RF feedthrough.

Another embodiment provides a system for transmitting/receiving a radio frequency signal, comprising a radio frequency device such as previously defined, positioned on a first surface of a printed circuit board, an antenna module being arranged on a second surface of the printed circuit board, and being coupled to the radio frequency device by means of a hole running through the printed circuit board, the antenna module comprising a waveguide and an antenna.

According to an embodiment, the through hole is an oblong hole, the largest dimension of the oblong hole being 2.53 mm and the smallest dimension of the oblong hole being 1.05 mm.

Another embodiment provides a method of manufacturing a laminate substrate such as previously defined, comprising the following steps: depositing the second metal layer and the third metal layer on either side of the second dielectric layer; forming laterally closed slots in the second metal layer and the third metal layer; depositing the first dielectric layer and the third dielectric layer on either side, respectively, of the second metal layer and the third metal layer; forming the first metal layer and the fourth metal layer on either side, respectively, of the first dielectric layer and the third dielectric layer; forming a slot open on one of its sides in the first metal layer, and forming a laterally closed slot in the fourth metal layer; forming a feed line, intended to be connected to a chip, the feed line being coplanar with the first metal layer and extending into the open slot; and at least one of the third metal layer or of the fourth metal layer having a portion protruding, respectively, into the third slot or into the fourth slot.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a simplified representation of a side view of a laminate substrate according to a specific embodiment;

FIG. 2A and FIG. 2B are simplified representations of a cross-section and side view of different laminate substrates according to two specific embodiments;

FIG. 3A, FIG. 3B, FIG. 3C, FIG. 3D are simplified representations in top view, respectively, of the first metal layer, of the second metal layer, of the third metal layer, and of the fourth metal layer of a substrate;

FIG. 3E is a simplified representation, in bottom view, of the fourth metal layer and of an oblong waveguide, according to another specific embodiment;

FIG. 4 is a simplified three-dimensional representation of a laminate substrate comprising the metal layers of FIGS. 3A to 3D and the oblong waveguide of FIG. 3E;

FIG. 5A, FIG. 5B, FIG. 5C, and FIG. 5D are simplified representations in top view, respectively, of the first metal layer, of the second metal layer, of the third metal layer, and of the fourth metal layer of a substrate;

FIG. 5E is a simplified representation, in bottom view, of the fourth metal layer and of an oblong waveguide, according to another specific embodiment;

FIG. 6 is a simplified three-dimensional representation of a laminate substrate comprising the metal layers of FIGS. 5A to 5D and the oblong waveguide of FIG. 5E;

FIG. 7A, FIG. 7B, FIG. 7C, and FIG. 7D are simplified representations in top view, respectively, of the first metal layer, of the second metal layer, of the third metal layer, and of the fourth metal layer of a substrate;

FIG. 7E is a simplified representation, in bottom view, of the fourth metal layer and of a thin oblong waveguide, according to another specific embodiment;

FIG. 8 is a simplified three-dimensional representation of a laminate substrate comprising the metal layers of FIGS. 7A to 7D and the waveguide of FIG. 7E;

FIG. 9A, FIG. 9B, FIG. 9C, and FIG. 9D are simplified representations in top view, respectively, of the first metal layer, of the second metal layer, of the third metal layer, and of the fourth metal layer of a substrate;

FIG. 9E is a simplified representation, in bottom view, of the fourth metal layer and of a thin oblong waveguide, according to another specific embodiment;

FIG. 10 is a simplified three-dimensional representation of a laminate substrate comprising the metal layers of FIGS. 9A to 9D and the waveguide of FIG. 9E;

FIG. 11A, FIG. 11B, FIG. 11C, FIG. 11D, and FIG. 11E are simplified representations in top view of the third metal layer of different substrates according to different specific embodiments;

FIG. 12A, FIG. 12B, FIG. 12C, FIG. 12D, and FIG. 12E are simplified representations in top view of the fourth metal layer of different substrates according to different specific embodiments;

FIG. 13A, FIG. 13B, FIG. 13C, and FIG. 13D are simplified representations in top view, respectively, of the first metal layer, of the second metal layer, of the third metal layer, and of the fourth metal layer of a substrate;

FIG. 13E is a simplified bottom view of the fourth metal layer and of an oblong waveguide, according to another specific embodiment;

FIG. 14A, FIG. 14B, FIG. 14C, and FIG. 14D are simplified representations in top view, respectively, of the first metal layer, of the second metal layer, of the third metal layer, and of the fourth metal layer of a substrate;

FIG. 14E is a simplified representation, in bottom view, of the fourth metal layer and of a thin oblong waveguide, according to another specific embodiment;

FIG. 14F and FIG. 14G are simplified three-dimensional representations, respectively, of a stack comprising the metal layers of FIGS. 14A, 14B, 14C, and 14D, and of a stack comprising the metal layers of FIGS. 14B, 14C, and 14D (the first metal layer of FIG. 14A not being shown herein in order to better visualize the vertical RF feedthrough formed in the substrate);

FIG. 15A, FIG. 15B, FIG. 15C, and FIG. 15D are simplified representations in top view, respectively, of the first metal layer, of the second metal layer, of the third metal layer, and of the fourth metal layer of a substrate;

FIG. 15E is a simplified representation, in bottom view, of the fourth metal layer and of a U-shaped waveguide, according to another specific embodiment;

FIG. 16 is a simplified representation of a cross-section view of a radio frequency device, according to another specific embodiment;

FIG. 17 is a simplified representation of a cross-section view of an RF signal transceiver system, according to another specific embodiment;

FIG. 18 is a graph showing the simulations of the S11, S22, and S21 parameters as a function of frequency for two laminate substrates according to different specific embodiments;

FIG. 19 is a simulation of a Smith chart of the S11 and S22 parameters for two laminate substrates according to different specific embodiments;

FIG. 20 is a simulation showing the propagation of electromagnetic waves (‘propagation of E-field’) in a transceiver system according to a specific embodiment of the invention;

FIG. 21 is a graph showing the simulations of the S11, S22, and S21 parameters as a function of frequency for a laminate substrate according to another specific embodiment;

FIG. 22 is a simulation of a Smith chart of the S11 and S22 parameters for a laminate substrate according to another specific embodiment;

FIG. 23 is a simulation showing the propagation of electromagnetic waves (‘propagation of E-field’) in a transceiver system according to another specific embodiment of the invention;

FIG. 24, FIG. 25, and FIG. 26 are graphs showing the obtained electrical performance of different devices having substrates according to different specific embodiments.

### DETAILED DESCRIPTION

The drawings are not necessarily to a uniform scale to make them easier to read.

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the applications of the described embodiments and the uses of the antenna are not described.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings. In particular, the term vertical propagation or vertical RF feedthrough refers to a RF propagation or feedthrough along the z axis.

Unless specified otherwise, the expressions “about”, “approximately”, “substantially”, and “in the order of” signify plus or minus 10%, preferably of plus or minus 5%. By between X and Y, there is meant that X and Y are included.

The substrate which will be described hereafter can be used for radio frequency applications. By radio frequency (RF), there is meant frequencies in the range from 3 kHz to 300 GHz, and more particularly frequencies in the range from 76 GHz to 81 GHz for the manufacturing of ADAS-type automotive radars. Although the disclosure refers in particular to frequencies of from approximately 76 GHz to 81 GHz, other frequencies may be used for other devices using other radio frequencies.

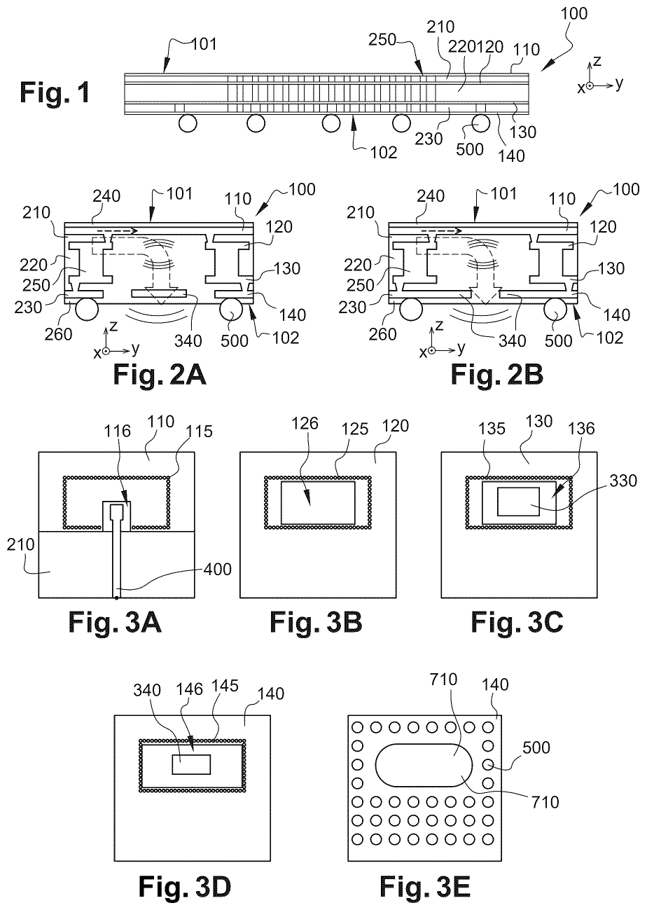

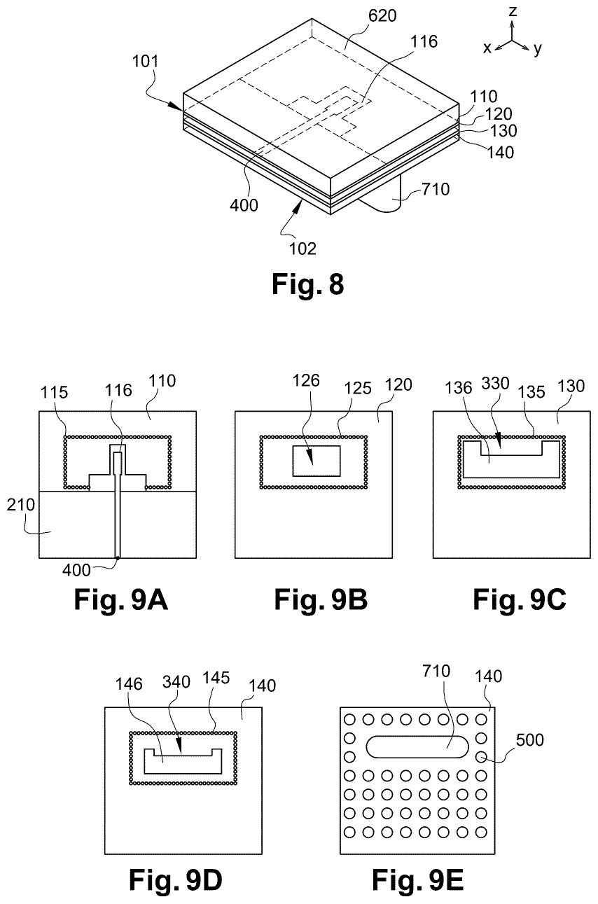

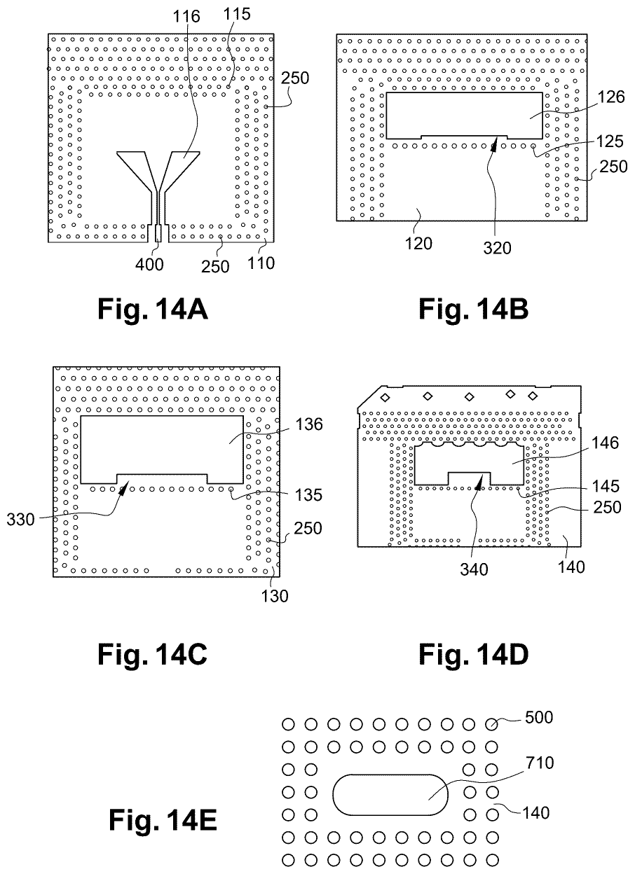

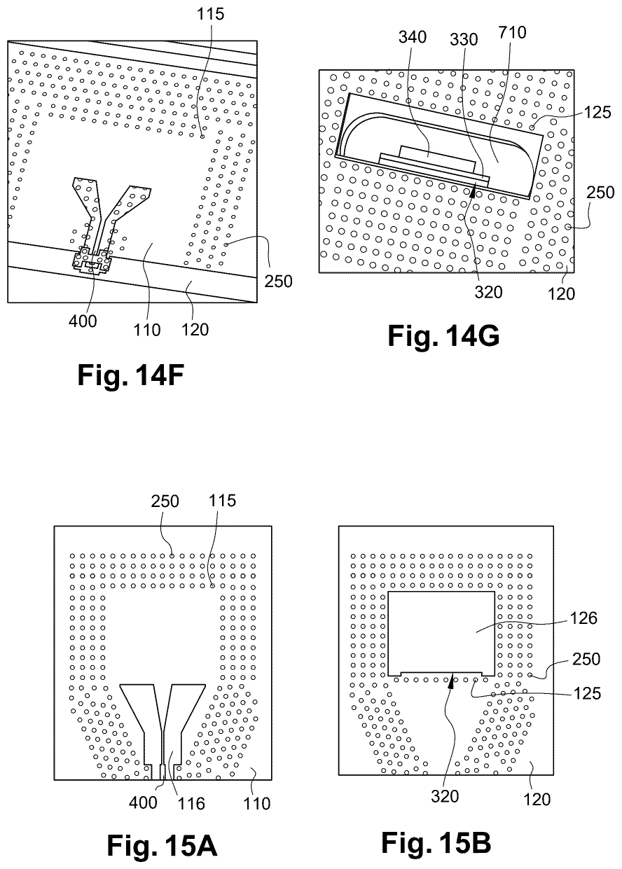

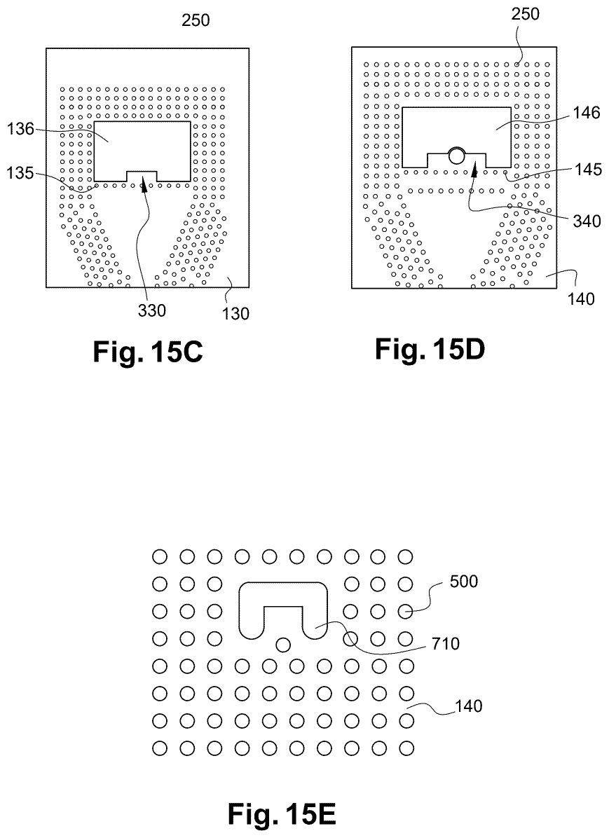

Laminate substrate 100 will now be described in more detail with reference to FIGS. 1, 2A and 2B, 3A to 3E, 4, 5A to 5E and 6, 7A to 7E and 8, 9A to 9E and 10, 11A to 11E, 12A to 12E, 13A to 13E, 14A to 14G, and 15A to 15E.

Laminate substrate 100 is a ball grid array (BGA) substrate.

Substrate 100 comprises a first main side 101 and a second main side 102 (FIGS. 1, 2A, and 2B).

The first main side 101 may be connected to a chip or to a plurality chips, and the second main side 102 may be assembled to a printed circuit board (PCB) 700. The second surface 102 of substrate 100 is covered with an array of balls 500. Balls 500 are connection pads enabling to bond substrate 100 to an external device 700, for example a printed circuit board. It is also possible to assemble two laminate substrates together, for example by mirroring them (‘U’ structure).

Substrate 100 comprises at least four metal layers 110, 120, 130, 140 from the first main side 101 to the second main side 102. The first metal layer 110 is located on the side of first surface 101. The fourth metal layer 140 is located on the side of second surface 102.

Four metal layers will be described hereafter, but there could be more than four metal layers (five or six, for example), for example by adding intermediate metal layers between the above-mentioned metal layers.

Metal layers 110, 120, 130, 140 may be made of a metal or of a metal alloy. They are for example made of a material selected from among gold, copper, aluminum, or an alloy of copper and aluminum. Metal layers 110, 120, 130, 140 have, for example, a thickness in the range from 5 to 50 μm, preferably from 5 to 35 μm, and even more preferably from 15 to 25 μm. Metal layers 110, 120, 130, 140 have, for example, a 40-μm thickness.

For example, metal layers 110, 120, 130, 140 are metal foils, particularly copper foils.

The second metal layer 120, the third metal layer 130, and the fourth metal layer 140 may have same dimensions or different dimensions. Their surfaces may be square or rectangular.

The first metal layer 110 may have a surface area smaller than the surface area of the other metal layers 120, 130, 140 (FIGS. 3A, 5A, 7A, 9A, for example).

The different metal layers 110, 120, 130, 140 are positioned one on top of the other. Metal layers 110, 120, 130, 140 are separated from one another by dielectric layers 210, 220, 230 so as to insulate them from one another.

A stack comprising an alternation of metal layers 110, 120, 130, 140 and of dielectric layers 210, 220, 230 (FIGS. 2A and 2B) is obtained. The stack of laminate substrate 100 successively comprises from the first main surface 101 to the second main surface 102: the first metal layer 110 (FIGS. 3A, 5A, 7A, 9A, 13A, 14A, 15A); the first dielectric layer 210; the second metal layer 120 (FIGS. 3B, 5B, 7B, 9B, 13B, 14B, 15B); the second dielectric layer 220; the third metal layer 130 (FIGS. 3C, 5C, 7C, 9C, 11A to 11E, 13C, 14C, 15C); the third dielectric layer 230; and the fourth metal layer 140 (FIGS. 3D, 5D, 7D, 9D, 12A to 12E, 13D and 13E, 14D and 14E, 15D, and 15E).

Additional dielectric layers 240, 260 may be arranged on either side of the previously-described stack to insulate metal layers 110, 140 (FIGS. 2A and 2B).

Dielectric layers 210, 220, 230, 240, 260 are made of a material enabling to transmit the electromagnetic field. Dielectric layers 210, 220, 230, 240, 260 are, for example, formed of a so-called prepreg material. By prepreg material, there is meant a composite material comprising a thermoplastic polymer or thermosetting resin and fillers, for example glass fibers. Dielectric layers may also be made of Ajinomoto's Insulation film® (referred to as ABF).

The second dielectric layer 220 forms the core of the stack and may be made of a different material than the other dielectric layers 210, 230, 240, 260. It is, for example, made of a resin that may contain fibers, in particular glass fibers, such as an epoxy resin containing glass fibers. It may also be made of a FR-4 (‘Flame Retardant 4’) material. The second dielectric layer 220 may have a thickness in the range from 100 to 150 μm.

Slots 116, 126, 136, 146 are formed in the metal layers 110, 120, 130, 140 of each level. The second slot 126, the third slot 136, and the fourth slot 146 are aligned along the z axis to form a vertical RF feedthrough. There is a 90-degree transition from the Quasi-TEM mode (microstrip or transmission line) to the TE mode (waveguide).

By slot, there is meant an area of the metal layer within which there is an absence of material, thus creating a void that extends through the entire thickness of the metal layer, creating a passage or hole that connects the two opposite surfaces of the metal layer. Once slot 116, 126, 136, 146 has been formed, this area may be filled with one or a plurality of materials. For example, this area may be filled, partially or totally, with the dielectric material of the lower or upper dielectric layer and/or with the matching element positioned within the slot (at the center of the slot or offset from the center of the slot). Slot 116, 126, 136, 146 preferably comprises at least four sides. It is for example rectangular. Slot 126, 136, 146 is said to be laterally closed when all its edges are surrounded by the metal layer. Slot 116 is said to be open when at least one of its edges is not formed by the metal layer.

The first slot 116 is formed in the first metal layer 110. The first slot 116 is an open slot having the transmission line 400 (also known as the feed line) extending into it. The transmission line is arranged coplanar with the first metal layer 110 (that is, they are in the same xy plane). Transmission line 400 is, for example, intended to be connected to chip 610. Transmission line 400 is made of metal. It may, for example, be made of copper, of aluminum, or of gold. Transmission line 400 comprises a longitudinal element, such as a wire or band, and an end. The end of the transmission line may have a square, rectangular, or triangular shape. The length and width of the transmission line depend on frequency.

At least a portion of transmission line 400 is positioned in the first slot 116. The end of transmission line 400 and at least a portion of the longitudinal element are positioned in slot 116. The flanks of transmission line 400 are not in contact with the first metal layer 110. The flanks of transmission line 400 are, for example, spaced apart from the edges of slot 116 by a distance in the range from 25 to 300 μm, for example a distance of 40 μm, 50 μm, or 200 μm. For some advanced technologies, it is possible to decrease the spacing to 10 or 12 microns, or even to 5 or 7 microns. The maximum spacing depends on the structure and on the position of the vias. For example, the spacing may range up to few millimeters. The various parameters are adjusted according to the frequency band and to the impedance.

According to a specific embodiment, the end of transmission line 400 may be insulated from metal layer 110. In other words, transmission line 400 extends into the first slot 116, the flanks and the end of the transmission line not being in contact with the first metal layer 110 (FIGS. 3A, 4, 5A, 6, 7A, 8, 9A, 10).

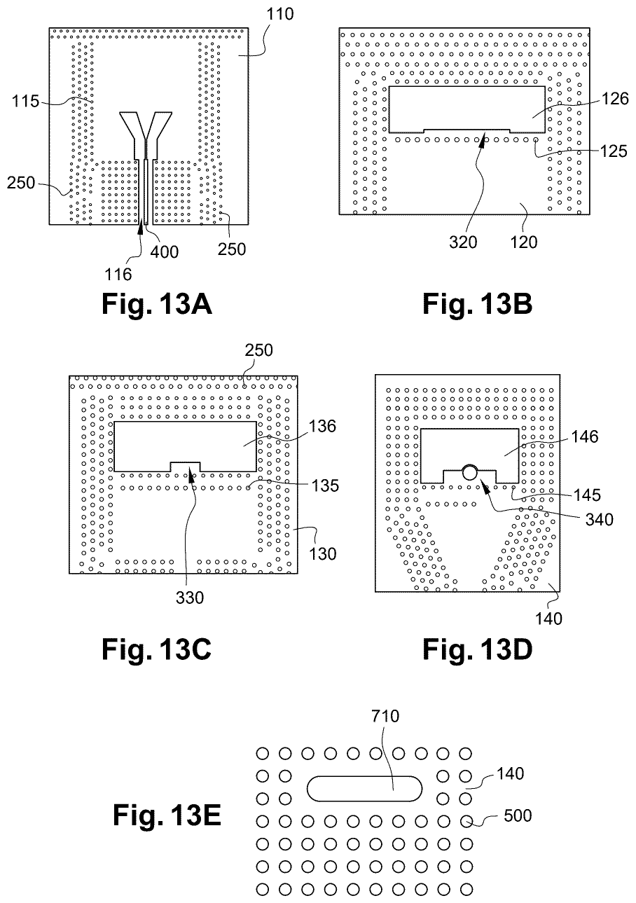

According to another specific embodiment, the end of transmission line 400 may be in contact with first metal layer 110 (FIGS. 13A, 14A and 15A). The end of the metal layers may be terminated by a block of vias which forms a slot.

In these various embodiments, first metal layer 110 and transmission line 400 form a first level of substrate 100 and play the role of an impedance transformer. Indeed, the impedance of chip 610 is at a value in the range from 45 to 50Ω and the waveguide of printed circuit board 700 is at a value in the range from 100 to 600Ω, or even from 200 to 600Ω. The impedance arriving in transmission line 400 is of 45-50Ω, it decreases and reaches, for example, 11Ω at the inlet of the substrate integrated waveguide (SIW), that is, at the second slot 126. At the outlet of the SIW of substrate 100, after the passage through the fourth slot 146, the impedance is at a value compatible with that of printed circuit board 700, for example at a 570-Ω value. As an illustration, impedances of 363Ω and 169Ω have been obtained for waveguides, respectively, of 2.54 mm×1.1 mm and 2.54 mm×0.55 mm.

The orientation of the signal is also changed by 90° between the first slot 116 and the second slot 126 (represented by arrows in FIGS. 2A and 2B), then allowing a vertical propagation of the signal through slots 136, 146.

The second metal layer 120 comprises a second slot 126. The second slot 126 is laterally closed. The second slot 126 may be positioned opposite transmission line 400 or offset from the position of transmission line 400. It is, for example, placed next to transmission line 400.

The third metal layer 130 comprises a third, laterally closed slot 136.

The fourth metal layer 140 comprises a fourth, laterally closed slot 146. Connection pads 500 (or balls) are positioned on the second surface 102 of substrate 100. They are bonded to the fourth metal layer 140. Connection pads 500 form an array of pads. There are no pads at the location of the fourth slot 146.

At least slots 126, 136, 146 are positioned one above the other along the z-axis, so as to form a vertical RF feedthrough and be able to transmit radio frequencies from chip 610 to PCB 700. The vertical RF feedthrough thus runs through the various levels of laminate BGA substrate 100. This maximum RF feedthrough maximizes the bandwidth without increasing the size or the insertion loss.

The second slot 126, the third slot 136, and the fourth slot 146 have dimensions different from one another and/or may be offset with respect to one another, with at least part of the slots overlapping along the z axis to form a vertical RF feedthrough.

For example, the fourth slot 146 has the largest dimensions and the first slot 116 has the smallest dimensions.

The size of the slot determines the frequency and the field of propagation to the waveguide (TE10).

At least one slot selected from among the second slot 126, the third slot 136, and the fourth slot 146 comprises a frequency matching element 320, 330, 340. Preferably, at least the fourth slot 146 comprises a matching element 340 (as for example shown in FIG. 2A and FIG. 2B).

In FIGS. 3A to 10, a matching element 330 is positioned in the third slot 136 and a matching element 340 may be positioned in the fourth slot 146.

It is possible to have a matching element 330 positioned in the third slot 136, a matching element 340 positioned in the fourth slot 146, as well as a matching element in the second slot 126 (FIGS. 13A to 15E).

Frequency matching elements 320, 330, 340 may have different dimensions. The frequency matching elements comprise two main sides and lateral surfaces. The surface of each main side is in the xy plane.

Depending on the desired characteristics, the frequency matching elements may be positioned at the center of the slot or on the edges of the slot and/or have different shapes. The matching elements are not necessarily aligned with one another.

Frequency matching elements 320, 330, 340 are configured to channel the electromagnetic signal into slots 126, 136, 146.

Matching elements 320, 330, 340 may be staggered to increase the bandwidth.

Matching elements 320, 330, 340 may partially overlap one another (along the z axis).

According to an embodiment, frequency matching element 320, 330, 340 may be a patch insulated from the edges of slot 126, 136, 146 by a gap (FIG. 2A, FIGS. 3A to 6). The patch is, for example, a metal plate. For example, it is a copper plate. The patch may be made of the same material as the metal layer. The patches are preferably made of a conductive material, preferably of a metal, for example of copper, aluminum, an alloy of copper and aluminum, or gold.

The patches are for example rectangular or square. They may also be circular.

The patches may have the same thickness as the metal layers, or a thickness identical to within 10% or even 5%.

According to another embodiment, impedance matching element 320, 330, 340 may be a portion of the metal layer which protrudes into the slot (FIG. 2B, FIGS. 7A to 12E, FIGS. 13A to 15E). In other words, a portion of the metal layer extends into the slot and forms an overhang or protrusion in slot 126, 136, 146. The protruding portion forms an inner extension of the metal plate.

It is needless to say that if the matching element is a portion of the metal layer protruding into the slot, the matching element will be positioned on the edge of the slot or in a corner of the slot.

The protruding portions are, for example, rectangular or square. The protruding portions have the same thickness as the metal layers.

The irregular shapes of the protruding portions and/or of the slot enable to match the frequency and the bandwidth.

As a non-limiting illustration, FIGS. 11A to 11Ea show a plurality of possible configurations of a third metal layer 130, having a portion 330 protruding into slot 136.

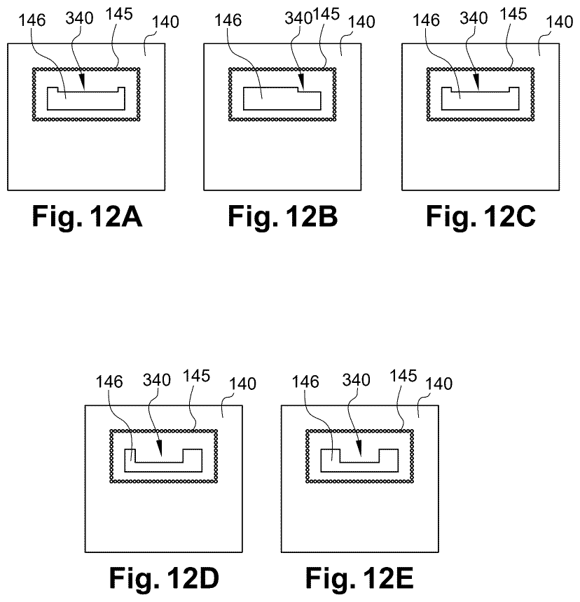

As a non-limiting illustration, FIGS. 12A to 12E show a plurality of possible configurations of a fourth metal layer 140, having a portion 340 protruding into slot 146.

These embodiments may be combined. It is possible, within a same device, to use patches for one or a plurality of levels and protruding portions for one or a plurality of levels.

The stack also comprises interlayer metal vias 250 formed through part of the layers in the stack or through all the layers in the stack, so as to be able to connect different metal layers 110, 120, 130, 140 to one another. The various interlayer metal vias enable to connect at least two metal layers to each other. They may connect more than two metal layers (for example three metal layers or four metal layers) together. The interlayer metal vias 250 may be stacked on one another or offset from one another.

At least one row of vias 115, 125, 135, 145, formed in each metal layer 110, 120, 130, and 140, surrounds, respectively, slots 116, 126, 136, 146. The rows of vias 115, 125, 135, 145 help confine electromagnetic waves within slot 116, 126, 136, 146 and/or prevent signal leakage. The various rows of vias 115, 125, 135, 145 are positioned one above the other along the z axis. It is possible to have a plurality of rows of vias 115, 125, 135, 145 per metal layer 110, 120, 130, 140.

Conductive layers 110, 120, 130, 140 and conductive vias 115, 125, 135, 145 form a waveguide-like structure, for example of rectangular shape. The RF signal is confined and guided through the substrate between the conductive plates, vias 115, 125, 135, 145 acting as side walls.

The use of a laminate substrate 100 comprising slots 116, 126, 136, 146 of different dimensions and/or offset from one another and/or slots 116, 126, 136, 146 comprising frequency matching elements 320, 330, 340 of different dimensions and/or offset from one another results in the obtaining of a wide-band, low-loss RF feedthrough for the desired frequencies. This stacking enables to adapt to the entire desired radio frequency band (in particular 76 GHz-81 GHz).

Moreover, with such a substrate 100, it is possible to obtain a bandwidth slightly wider than the frequency range conventionally used in automotive radars (76 GHz-81 GHz), which enables to be less sensitive to manufacturing.

It is possible to size slots 116, 126, 136, 146 and matching elements 320, 330, 340 according to the operating frequency and/or to the substrate.

The size of the device is decreased as compared with conventional technologies, particularly those using patch antennas. A full integration into substrate 100 is obtained.

The thickness of substrate 100 is, for example, in the range from 100 to 900 μm, for example from 100 to 200 μm, for example in the order of 150 μm, or between 200 and 300 μm.

This compact, high-performance feedthrough may be formed by means of a standard technology for a laminate substrate 100. Costs are thus decreased.

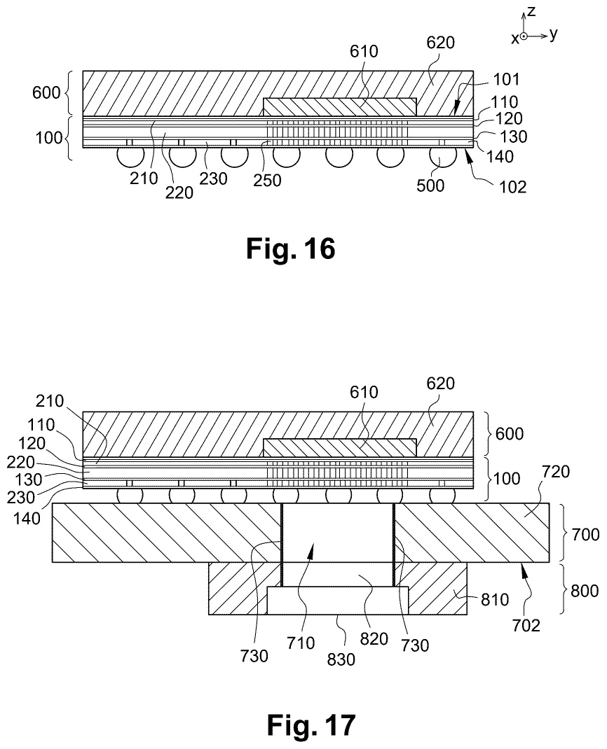

The above-described substrate 100 may be used in a radio frequency device (FIG. 16) or an RF signal transceiver system (FIG. 17).

The radio frequency device comprises laminate substrate 100 and a package 600 comprising at least one electronic component and, in particular, at least one radio frequency component 610 molded in an insulating material 620, such as a polymer or resin.

Radio frequency component 610 is an electronic component capable of transmitting and receiving specific radio frequency signals.

In particular, radio frequency component 610 is a radio frequency chip 610.

Chip 610 has on its front side connection areas covered by metal bumps (not shown). The metal bumps are, for example, made of tin or of a tin-based alloy.

Radio frequency component 610 is assembled on substrate 100.

Chip 610 is directly mounted on laminate BGA substrate 100, the bumps of chip 610 facing the side of the first surface of substrate 100 (‘flip-chip’). Chip 610 is connected to the BGA substrate by its bumps. It could be bonded to the substrate by wire bonding.

Chip 610 is connected to the transmission line 400 of substrate 100, for example by means of microstrips.

The RF signal transceiver system comprises the radio frequency device, positioned on a first surface 701 of a printed circuit board (PCB) 700, and an antenna module 800 arranged on a second surface 702 of printed circuit board 700.

Antenna module 800 comprises a substrate 810 having a waveguide 820 and antennas 830 formed therein.

The printed circuit board 700 used is, for example, manufactured by forming through holes 710 in substrate 700 and metallizing them. The side walls 730 of through holes 710 confine the electromagnetic waves. The top and bottom surfaces of substrate 700 may also be metallized to form the waveguide.

Antenna module 800 is coupled to the radio frequency device via holes 710 running through printed circuit board 720. The signal is transmitted continuously from chip 610 to PCB 700, then to the waveguide 820 and to the antenna 830 of antenna module 800.

BGA substrate 100 is bonded to printed circuit board 700. In particular, the balls 500 of the BGA are soldered to printed circuit board 700. The balls 500 of the BGA are, for example, made of tin or of a tin alloy, such as SAC (alloy of tin, silver, and copper).

Part of the balls 500 of the BGA play the role of a short waveguide to transmit the signal to PCB 700.

The signal is thus routed through BGA substrate 100, via the vertical RF feedthrough, to the holes 710 formed in printed circuit board 700 and then to antenna module 800.

Substrate 100 may be manufactured according to the following steps: depositing the second metal layer 120 and the third metal layer 130 on either side of the second dielectric layer 220; forming laterally closed slots 126, 136 in the second metal layer 120 and the third metal layer 130; depositing the first dielectric layer 210 and the third dielectric layer 230 on either side of the previously-deposited metal layers 120, 130; forming the first metal layer 110 and the fourth metal layer 140 on either side of the first dielectric layer 210 and of the third dielectric layer 230; forming a slot 116 open on one of its sides in the first metal layer 110, and forming a laterally closed slot 146 in the fourth metal layer 140; and forming a feed line 400, intended to be connected to a chip, feed line 400 extending into the open slot 116.

Slots 116, 126, 136, 146 may be formed, for example, by microfabrication techniques such as lithography and etching.

Slots 116, 126, 136, 146 have different dimensions. The closed slot 146 of the fourth metal layer 140 has the largest dimensions and the open slot 116 of the first metal layer 110 has the smallest dimensions.

If the device comprises one or a plurality of matching elements in the form of metal plates, the method will also comprise one or a plurality of steps during which the metal plate(s) are positioned in the corresponding slots.

The method may also comprise a step during which connection pads 500 are bonded to the fourth metal layer.

### Non-Limiting Illustrative Examples

### Example 1 and Example 2: Substrates with Metal Plates (‘Patches’) in Slots

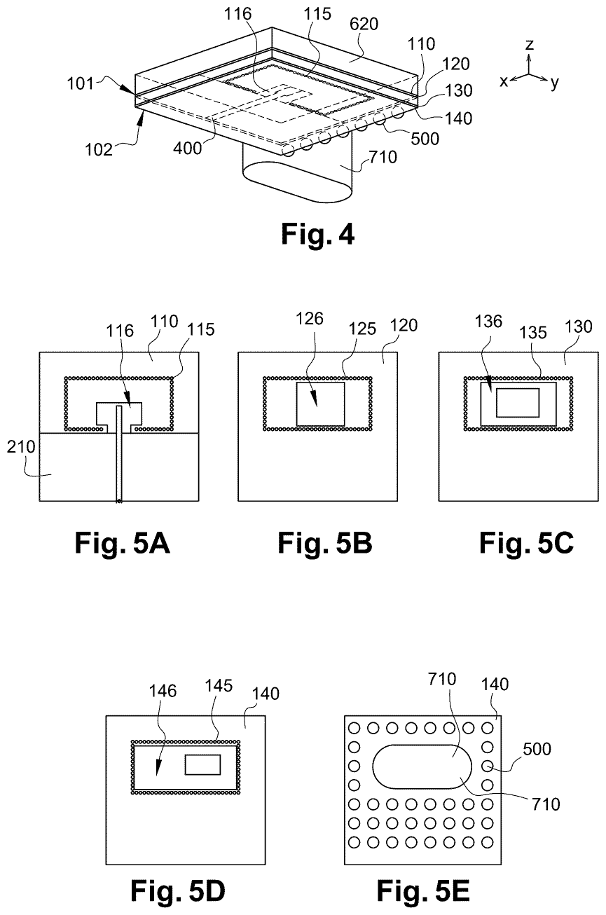

In a first example, BGA substrate 100 is formed of the various elements shown in FIGS. 3A to 3E and 4. A metal plate is arranged in the third metal layer 130 and in the fourth metal layer 140.

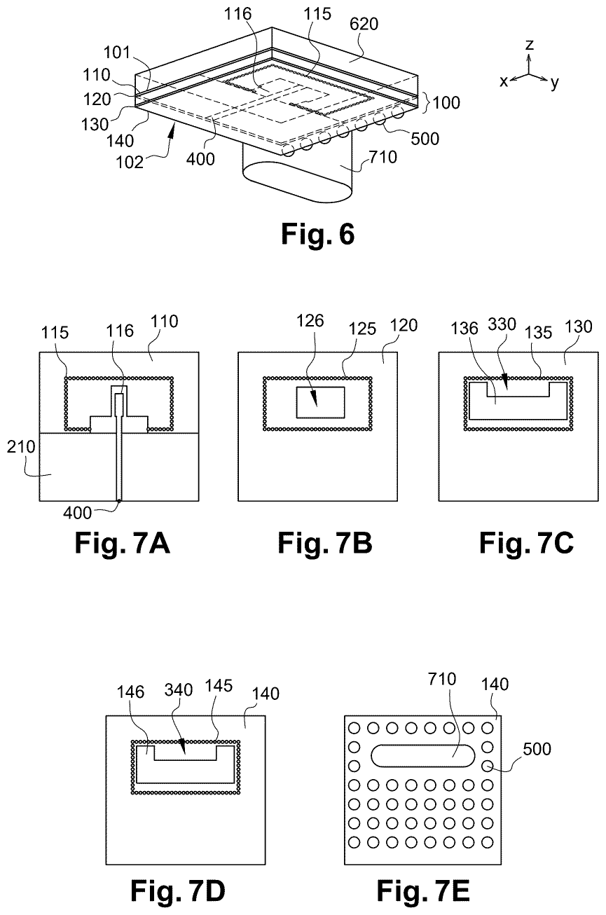

In a second example, BGA substrate 100 is formed of the various elements shown in FIGS. 5A to 5E and 6. A metal plate is arranged in the third metal layer 130 and in the fourth metal layer 140.

The main differences between the two examples are the following: the connection line 400 of the first level is different, and the spaces between transmission line 400 and the first slot 116 are different; this enables to adapt the bandwidth; the second slot 126 is smaller in Example 2 than that of Example 1, to achieve a resonance at higher frequency; the fourth slot 146 is wider in Example 2 than that of Example 1, and the plate 340 of the fourth slot 146 is offset in Example 2 to achieve a resonance at lower frequency.

The third level of Example 2 is identical to that of Example 1.

In each example, a PCB 700 is assembled to BGA substrate 100. PCB 700 features oblong through holes 710 of 2.54 mm×1.1 mm acting as waveguides all the way to the antenna module.

A transmission line 400 is coupled to a bump positioned on the BGA substrate, and is connected to the SIW (Substrate Integrated Waveguide).

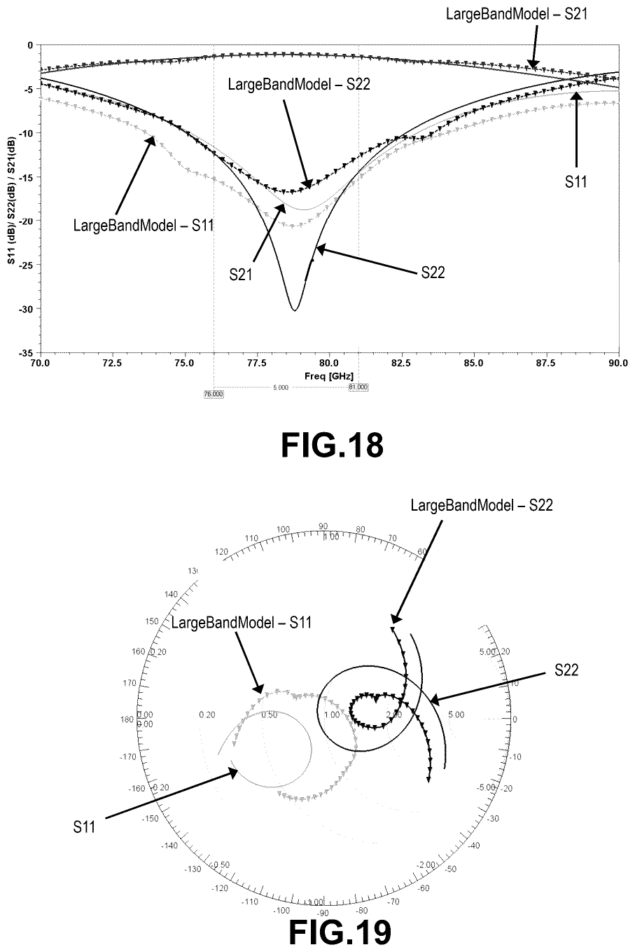

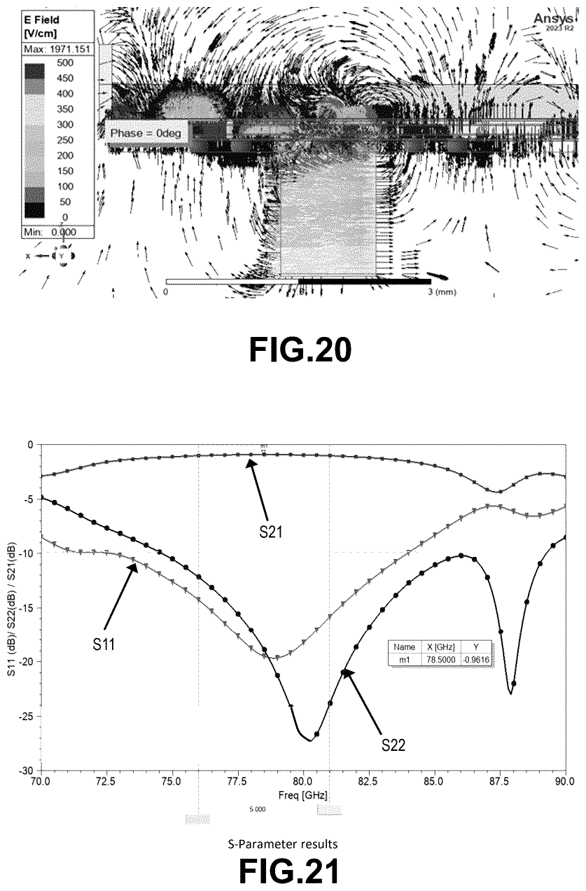

The performance of the two devices has been simulated (FIGS. 18 to 20).

In the first example, the following performance is obtained: −12 dB/−S11 (76 GHZ-81 GHz).

In the second example, the following performance is obtained: −15 dB/S11 (76 GHz-81 GHz), S21: −1.05 dB more flexibility on S11/S22 (less than −10 dB) due to the band widening.

Both examples have a good performance.

The device of Example 1 has a narrow bandwidth adaptation to the operating bandwidth as compared with version 2.

The device of Example 2 has a better adaptation from the input, which slightly improves the performance in the lower and upper bands.

However, it should be noted that both Example 1 and Example 2 operate at the desired frequencies (76 GHz-81 GHZ) and have the expected performance.

### Example 3: Substrate with Metal Plates, Among which Part of the Plates Protrude into Slots

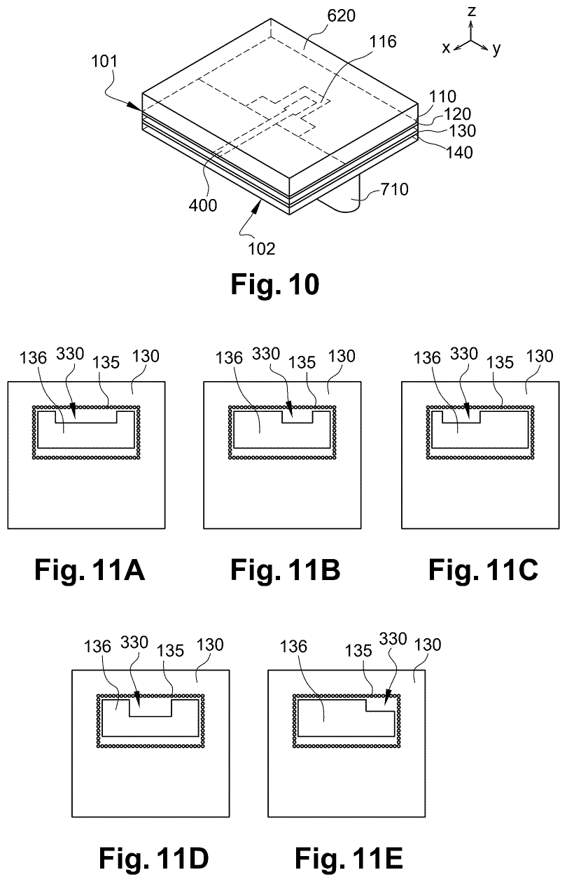

In this third example, BGA substrate 100 is formed of the various elements shown in FIGS. 9A to 9E and 10. A portion 330 of the third metal layer 130 and a portion 340 of the fourth metal layer 140 protrude, respectively, into the third slot 136 and into the fourth slot 146.

As compared with Examples 1 and 2, the device of Example 3 exhibits a size reduction of approximately 34%.

A PCB 700 is assembled to BGA substrate 100. PCB 700 features oblong through holes 710 of 2.54 mm×0.55 mm acting as a waveguide all the way to the antenna module. The size of the waveguide is considerably decreased (by in the order of 50% along the length of the oblong section).

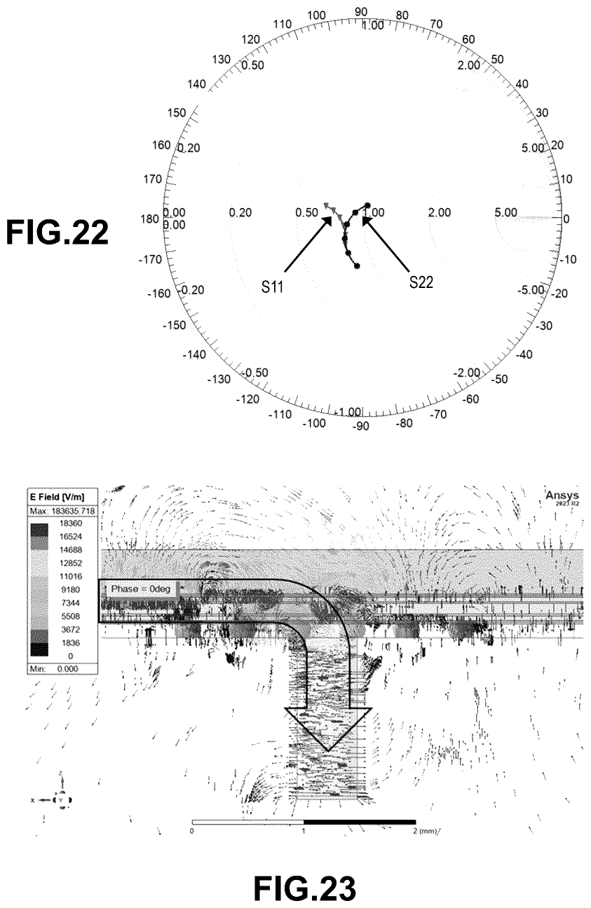

The performance of the device was estimated by simulation of the ‘Scattering Parameters’ (S-parameters). The parameters reflect the transmission and reflection properties of high-frequency gratings. Parameters S11 and S22 are smaller than −10 dB, and S21 is −0.96 dB: the obtained device has a good performance (FIGS. 21 to 23). EM wave propagation shows that there is no loss of energy to the outside of the device.

With an RF signal extension of 400-μm length and a width in the range from 160 to 180 μm, and a die escape extension having a length between 120 and 155 μm long and a 30-μm width, the following characteristics are obtained: S11: −23 to −20 dB at 76 GHz-81 GHz (Specification: −20 dB min); S21: −1.2 dB to −1.4 dB at 76 GHz-81 GHz (Specification: −1.5 dB max).

### Example 4: Substrate with Metal Plates, in which Part of the Plates Protrude into Slots

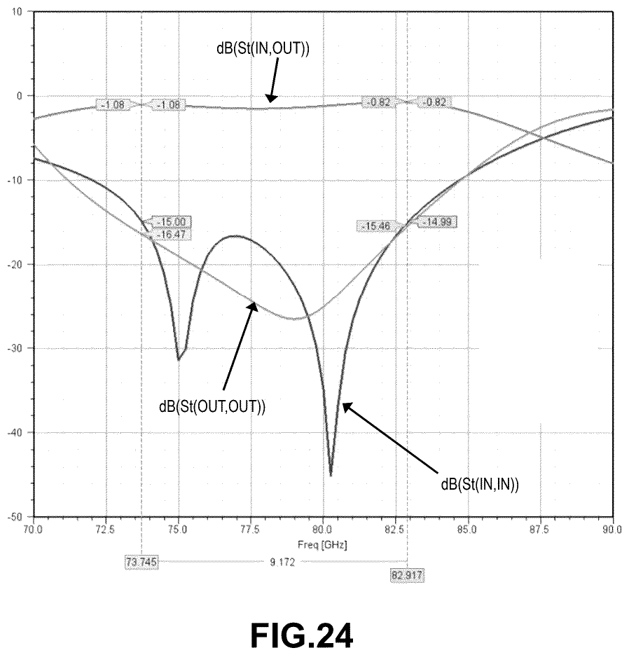

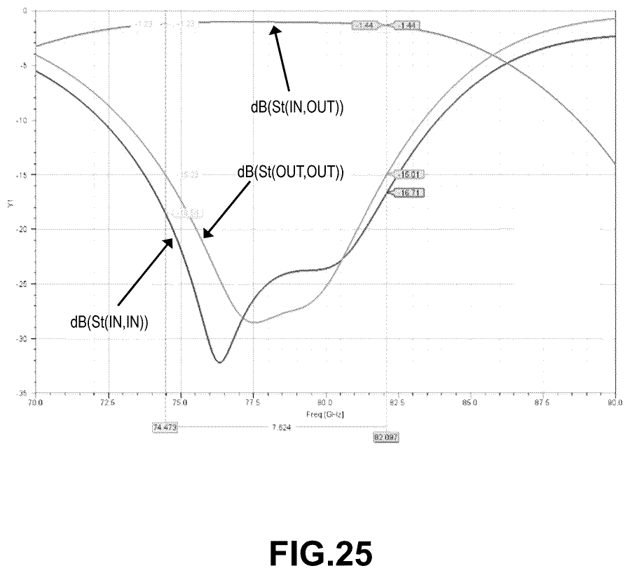

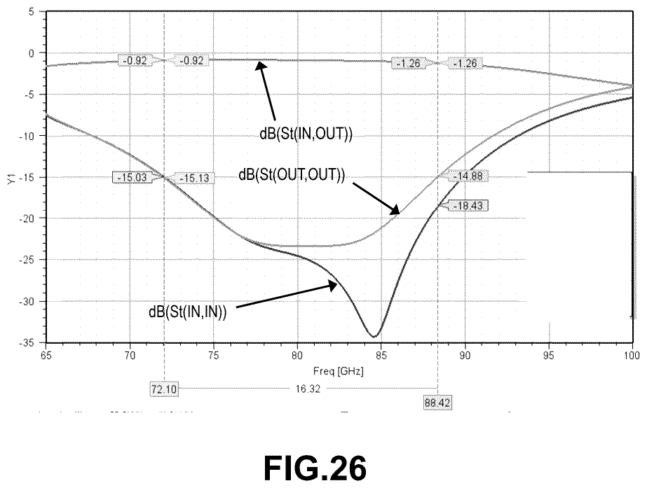

The performance of the devices shown in FIGS. 13A to 13E, 14A to 14F and 15A to 15E have been simulated. The obtained results are shown, respectively, in FIGS. 24 to 26. They show that a very wide bandwidth is obtained in the desired frequency range. This decreases the sensitivity due to manufacturing tolerances.

A performance of S11 and S22 lower than −30 dB and S12 and S21 higher than −0.5 dB can be achieved.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A laminate substrate for an RF application comprising, from a first main side to a second main side:
a first metal layer and a transmission line, a first slot open on one of its sides being formed in the first metal layer, the transmission line being coplanar with the first metal layer and penetrating into the first slot;
a second metal layer comprising a second, laterally closed slot;
a third metal layer comprising a third laterally closed slot;
a fourth metal layer comprising a fourth slot;
a dielectric layer being arranged between each metal layer;
the second slot, the third slot, and the fourth slot forming a vertical RF feedthrough in the laminate substrate; and
at least one of the third metal layer or of the fourth metal layer having a portion protruding, respectively, into the third slot or into the fourth slot.

2. The laminate substrate according to claim 1, wherein the portion of the fourth metal layer protrudes into the fourth slot, and connection pads are bonded to the fourth metal layer forming the second main side.

3. The laminate substrate according to claim 1, wherein the third metal layer and the fourth metal layer each have a portion protruding, respectively, into the third slot and into the fourth slot.

4. The laminate substrate according to claim 3, wherein the protruding portions have different dimensions.

5. The laminate substrate according to claim 3, wherein the protruding portions are offset from one another.

6. The laminate substrate according to claim 1, wherein a thickness of the laminate substrate is in a range from 100 to 200 μm.

7. The laminate substrate according to claim 1, wherein each protruding portion is rectangular.

8. The laminate substrate according to claim 1, wherein the second slot, the third slot, and the fourth slot have different dimensions.

9. The laminate substrate according to claim 1, wherein the fourth slot has dimensions greater than dimensions of the second slot.

10. A radio frequency device, comprising:
the laminate substrate of claim 1;
a radio frequency chip mounted on the first surface of the substrate, the radio frequency chip being connected to the feed line, whereby the radio frequency chip is coupled to the vertical RF feedthrough.

11. A system for transmitting/receiving a radio frequency signal, comprising:
the radio frequency device of claim 10, positioned on a first surface of a printed circuit board, an antenna module being arranged on a second surface of the printed circuit board, and being coupled to the radio frequency device by means of a hole running through the printed circuit, the antenna module comprising a waveguide and an antenna.

12. The system according to claim 11, wherein the through hole is an oblong hole, the largest dimension of the oblong hole being 2.53 mm and the smallest dimension of the oblong hole being 1.05 mm.

13. A method of manufacturing the laminate substrate of claim 1 comprising the following steps:
depositing the second metal layer and the third metal layer on either side of the second dielectric layer;
forming laterally closed slots in the second metal layer and the third metal layer;
depositing the first dielectric layer and the third dielectric layer on either side, respectively, of the second metal layer and the third metal layer;
forming the first metal layer and the fourth metal layer on either side, respectively, of the first dielectric layer and the third dielectric layer;
forming a slot open on one side in the first metal layer, and forming a laterally closed slot in the fourth metal layer;
forming a feed line, intended to be connected to a chip, the feed line being coplanar with the first metal layer and extending into the open slot;
wherein at least one of the third metal layer or of the fourth metal layer having a portion protruding, respectively, into the third slot or into the fourth slot.

14. The method according to claim 13, wherein the portion of the fourth metal layer protrudes into the fourth slot, and further comprising bonding the connection pads to the fourth metal layer to form the second main side of the laminate substrate.

15. The method according to claim 13, wherein a thickness of the laminate substrate is in a range from 100 to 200 μm.

16. The method according to claim 13, wherein each protruding portion is rectangular.

17. The method according to claim 13, wherein the second slot, the third slot, and the fourth slot have different dimensions.

18. The method according to claim 13, wherein the fourth slot has dimensions greater than dimensions of the second slot.
